(19) United States
(12) Patent Application Publication
(10) Pub. No.: US 2015/0325723 A1
(43) Pub. Date: Nov. 12, 2015

(54) POLYCRYSTALLINE PHOTODETECTORS AND METHODS OF USE AND MANUFACTURE

(71) Applicant: THE BOARD OF REGENTS OF THE UNIVERSITY OF OKLAHOMA, Norman, OK (US)

(72) Inventor: Zhisheng Shi, Norman, OK (US)

(21) Appl. No.: 14/652,008

(22) PCT Filed: Dec. 13, 2013
(86) PCT No.: PCT/US2013/075110

§ 371 Date: Jun. 12, 2015

Related U.S. Application Data
(60) Provisional application No. 61/736,987, filed on Dec. 13, 2012.

(51) Int. Cl. H01L 31/032; H01L 31/18; H01L 31/0216; H01L 27/146; H01L 31/0368

(52) U.S. Cl. CPC H01L 31/0324; H01L 27/14669; H01L 27/14627; H01L 27/1462; H01L 31/0368; H01L 31/02161; H01L 31/18

(57) ABSTRACT

Method and apparatus for semiconductor devices are presented. The method may be performed by applying a layer of polycrystalline material to a surface of a substrate. The polycrystalline layer may be a lead salt semiconductor material. The method is further performed by applying junctions and two or more spaced apart electrical contacts to the polycrystalline material to create a photovoltaic device in which changes in light interacting with the polycrystalline material causes changes in voltage at the junctions thereby enabling photodetection.

### INCORPORATION BY REFERENCE

The present patent application hereby incorporates by reference the entire content of the provisional patent application filed on Dec. 13, 2012 and identified by U.S. Ser. No. 61/736,987.

### BACKGROUND

Conventional photovoltaic cameras are made of focal plane arrays (FPA) that consist of pixels with typical size in tens of micrometers. For the best material quality, continuous single-crystalline films are grown on a substrate. The substrate serves as a seed crystal as well as mechanical support for device fabrication. FPAs of the epitaxial films are then fabricated with processing technology. However, due to the availability, scalability, functionality, and sometimes cost concerns, dissimilar substances are often used. The mismatches of lattice constant, thermal expansion coefficient, and crystal structure between the dissimilar substrate and the epitaxial films introduce defects such as dislocations and thus lead to inferior crystal quality and device performance. Studies have been carried out to eliminate or reduce those defects, including buffer layer techniques, strained layers, lateral growth, selected area growth, and ex-situ treatment techniques such as annealing. For many material systems, however, the success is limited by the nature of fundamental material physics.

Polycrystalline thin films of lead salt materials that consist of micro-size crystals have been used to fabricate uncooled mid-infrared (MWIR) photoconductive (PC) detectors. Commercial Pb-salt PC detectors can operate at room temperature but with slow response time and relatively low detectivity due to photoconductive type of detection. Mid/long-wave (MWIR and LWIR) photovoltaic (PV) detectors operating at room temperature with fast response time and high detectivity have long been sought after but have not yet been realized. Despite high material quality, polycrystalline semiconductor made of micro-size self-crystallized crystals has not been considered, in conventional wisdom, to be suitable for PV junction detector fabrication.

Antireflective coatings may be applied to optoelectronic devices, such as solid state lighting devices, solar cells, and infrared light emitters and detectors. Light coupling efficiency between devices and their ambient environment is a vital factor affecting performance. Conventional thin film anti-reflective coatings can only enhance light coupling in a narrow incident of angle and for a certain small wavelength range.

### BRIEF DESCRIPTION OF THE DRAWINGS

Several embodiments of the present disclosure are hereby illustrated in the appended drawings. It is to be noted however, that the appended drawings only illustrate several typical embodiments and are therefore not intended to be considered limiting of the scope of the present disclosure. Further, in the appended drawings, like or identical reference numerals may be used to identify common or similar elements and not all such elements may be so numbered. The figures are not necessarily to scale and certain features and certain views of the figures may be shown exaggerated in scale or in schematic in the interest of clarity and conciseness.

FIG. 1 is a schematic view of an embodiment of a photoconductive device in accordance with the present disclosure.

FIG. 2 is a block diagram of an embodiment of a method for creating the photoconductive device of FIG. 1.

FIG. 3a is a top plan view of a layer of polycrystalline material applied to a substrate in accordance with an embodiment of the present disclosure.

FIG. 3b is a cross-sectional view of the layer of polycrystalline material of FIG. 3a.

FIG. 4a is a top plan view of a layer of polycrystalline material applied to a substrate in accordance with an embodiment of the present disclosure.

FIG. 4b is a cross sectional view of the layer of polycrystalline material of FIG. 4a.

FIG. 5 is a schematic view of an embodiment of a photovoltaic device in accordance with an embodiment of the present disclosure.

FIG. 6 is a partial, side-elevational view of a portion of the substrate of the photovoltaic device depicted in FIG. 5 having an anti-reflective coating in accordance with some embodiments of the present disclosure.

FIG. 7 is a block diagram of an embodiment of a method for creating the photovoltaic device of FIG. 5.

FIG. 8 is an exploded schematic view of a night vision semiconductor device in accordance with an embodiment of the present disclosure.

FIG. 9 is a block diagram of an embodiment of a method for applying an antireflective coating to a substrate in accordance with the present disclosure.

FIG. 10 is a perspective view of a compound-eye detector constructed in accordance with some embodiments of the present disclosure.

### DETAILED DESCRIPTION

Before explaining the several embodiments of the presently described inventive concepts in detail by way of exemplary drawings, experimentation, results, and laboratory procedures, it is to be understood that the inventive concepts are not limited in its application to the details of construction and the arrangement of the components set forth in the following description or illustrated in the drawings, experimentation and/or results. The inventive concepts are capable of other embodiments or of being practiced or carried out in various ways. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting.

Unless otherwise defined herein, scientific and technical terms used in connection with the presently disclosed inventive concepts shall have the meanings that are commonly understood by those of ordinary skill in the art. Further, unless otherwise required by context, singular terms shall include pluralities and plural terms shall include the singular. Generally, nomenclatures utilized herein are those well-known and commonly used in the art. The nomenclatures utilized herein are those well-known and commonly used in the art.

All patents, published patent applications, and non-patent publications mentioned in the specification are indicative of the level of skill of those skilled in the art to which the presently disclosed inventive concepts pertain. All patents, published patent applications, and non-patent publications referenced in any portion of this application are herein expressly incorporated by reference in their entirety to the same extent as if each individual patent or publication was specifically and individually indicated to be incorporated by reference.

All of the devices, apparatus, and/or methods disclosed herein can be made and executed without undue experimentation in light of the present disclosure. While the components and methods of this disclosure have been described in terms of particular embodiments, it will be apparent to those of skill in the art that variations may be applied to the components and/or methods and in the steps or in the sequence of steps of the methods described herein without departing from the concept, spirit and scope of the disclosure. All such similar substitutes and modifications apparent to those skilled in the art are deemed to be within the spirit, scope and concept of the inventive concepts as disclosed herein.

As utilized in accordance with the present disclosure, the following terms, unless otherwise indicated, shall be understood to have the following meanings:

Unless expressly stated to the contrary, “or” refers to an inclusive or and not to an exclusive or. For example, a condition A or B is satisfied by anyone of the following: A is true (or present) and B is false (or not present), A is false (or not present) and B is true (or present), and both A and B are true (or present). The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Use of the “a” or “an” are employed to describe elements and components of the embodiments herein. This is done merely for convenience and to give a general sense of the inventive concept. This description should be read to include one or at least one and the singular also includes the plural unless otherwise stated. The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” The use of the term “at least one” will be understood to include one, as well as any quantity more than one, including, but not limited to, for example, 2, 3, 4, 5, 6, 7, 8, 9, 10, 15, 20, 30, 40, 50, 100, or greater. The term “at least one” may extend up to 100 or 1000 or more, depending on the term to which it is attached; in addition, the quantities of 100/1000 are not to be considered limiting, as higher limits may also produce satisfactory results in certain embodiments. In addition, the use of the term “at least one of X, Y and Z” (where X, Y and Z are intended to represent, for example, three or more objects) will be understood to include X alone, Y alone, and Z alone, as well as any combination of X, Y and Z, such as X and Y, X and Z, or Y and Z.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open ended and do not exclude additional, unrecited elements or method steps.

As used herein any references to “one embodiment,” “an embodiment,” or “some embodiments” means that a particular element, feature, structure, or characteristic described in connection with the embodiment is included in at least one embodiment. The appearances of the phrase “in one embodiment” in various places in the specification may not refer to the same embodiment.

The term “about” is used to indicate that a value includes the inherent variation or error for the device, the method being employed to determine the value and/or the variation that exists among study items. For example but not by way of limitation, when the term “about” is utilized, the designated value may vary by +/−15%, +/−12%, or +/−11%, or +/−10%, or +/−9%, or +/−8%, or +/−7%, or +/−6%, or +/−5%, or +/−4%, or +/−3%, or +/−2%, or +/−1%, or +/−0.5%. As used herein the symbol “+/−” indicates “plus or minus”.

As used herein, the term “substantially” means that the subsequently described event or circumstance completely occurs or that the subsequently described event or circumstance occurs to a great extent or degree. For example, in certain embodiments, the term “substantially” means that the subsequently described event or circumstance occurs at least 90% of the time, or at least 91% of the time, or at least 92% of the time, or at least 93% of the time, or at least 94% of the time, or at least 95% of the time, or at least 96% of the time, or at least 97% of the time, or at least 98% of the time, or at least 99% of the time. Also, the term “substantially” will be understood to allow for minor variations and/or deviations that do not result in a significant impact thereto.

While the presently disclosed inventive concepts will now be described in connection with particular embodiments in the following examples so that aspects thereof may be more fully understood and appreciated, it is not intended to limit the presently disclosed inventive concepts to these particular embodiments. On the contrary, it is intended to cover all alternatives, modifications and equivalents as may be included within the scope of the presently disclosed inventive concepts as described herein. Thus, the following description serves to illustrate the practice of this presently disclosed inventive concepts, it being understood that the particular embodiments shown and discussed are by way of example and for purposes of illustrative discussion of the presently disclosed inventive concepts only and are presented in the cause of providing what is believed to be the most useful and readily understood description of formulation procedures and methods as well as of the principles and conceptual aspects of the presently disclosed inventive concepts. As such, the embodiments described below are meant to be exemplary, not exhaustive.

The present disclosure includes photodetector devices which comprise a substrate having a polycrystalline material disposed thereon for receiving light. In one aspect, embodiments of the present disclosure are directed to photovoltaic devices. The photovoltaic device is described as having a substrate having a surface, a layer of polycrystalline material applied to the surface of the substrate, and two or more spaced apart electrical contacts connected to the layer of polycrystalline material. The layer of polycrystalline material may be sensitized to enhance or create an ability to receive and interact with light. Changes in light interacting with the layer of polycrystalline material changes a resistance to conducting electricity within the layer of polycrystalline material. The changes in the resistance to conducting electricity is registered by the two or more spaced apart electrical contacts. The layer of polycrystalline material in the present disclosure is a thin film material defined as having boundary domains existing along at least one dimension between crystallites therein. The size of crystallites in the layer of polycrystalline material can be in micro- or nano-meter scale. For example, thin films consisting of one dimensional column crystals (either in micro- or nano-scale) are considered polycrystalline thin film materials.

In another embodiment, the present disclosure is directed to a method performed by applying a layer of polycrystalline material to a surface of a substrate. The polycrystalline material may be sensitized to enhance or create an ability in the polycrystalline material to receive and interact with the light. The method is further performed by isolating a first crystal (or set of first crystals) from a second crystal (or set of second crystals), and applying one or more spaced apart first electrical contacts to the first crystal or set of first crystals of the polycrystalline material, applying one or more spaced apart second electrical contacts to the second crystal or set of second crystals of the polycrystalline material to create a compound eye photoconductive device in which changes in light interfacing with the polycrystalline material changes the polycrystalline material's resistance to conducting electricity.

In another aspect, embodiments of the present disclosure are directed to photovoltaic photodetector devices described as having a substrate having a surface, a layer of polycrystalline material applied to the surface of the substrate, a junction layer applied to the polycrystalline material, and two or more spaced apart electrical contacts connected to the junction layer and the substrate. The layer of polycrystalline material may be sensitized to enhance or create an ability to receive and interact with light. The junction layer is applied to a surface of the layer of polycrystalline material opposite a surface of the layer of polycrystalline material in contact with the substrate. The junction layer enables changes in light interacting with the layer of polycrystalline material to create a change at the junction layer. The two or more spaced apart electrical contacts enable generation of a voltage or electrical current based on changes in light interacting with the polycrystalline material and the junction layer.

In another embodiment of the present disclosure, a method is presented and performed by applying a layer of polycrystalline material to a surface of a substrate. The polycrystalline material may be sensitized to enhance or create the polycrystalline material's ability to receive and interact with the light. The method is further performed by applying a junction layer to the polycrystalline material to enable changes in light interacting with the polycrystalline material to create a change at the junction layer. Two or more spaced apart electrical contacts are applied to the polycrystalline material and the substrate to create a photovoltaic device which generates a voltage or electrical current based on changes in light interacting with the polycrystalline material and the junction layer.

In one aspect of the disclosure, embodiments are directed to a night vision semiconductor device. The night vision semiconductor device has a curved substrate having a first surface forming an inner curve and a second surface, opposite the first surface, forming an outer curve. The night vision semiconductor device also includes a layer of polycrystalline material applied to the first surface of the substrate, a junction layer applied to the layer of polycrystalline material, a plurality of spaced apart electrical contacts connected to the junction layer and the substrate, a microchannel plate, a vacuum tube disposed between the plurality of spaced apart electrical contacts and the microchannel plate, and one or more electronics electrically connected to the microchannel plate. The layer of polycrystalline material may be sensitized to enhance or create an ability to receive and interact with light. The junction layer is applied to a surface of the layer of polycrystalline material opposite a surface of the layer of polycrystalline material in contact with the substrate. The junction layer enables changes in light interacting with the layer of polycrystalline material to create changes at the junction layer. The plurality of spaced apart electrical contacts act to emit electrons. The microchannel plate is configured to receive electrons emitted from the plurality of spaced apart electrical contacts and generate information indicative of a pattern at which the electrons strike the microchannel plate. The vacuum tube is configured to allow electrons emitted from the plurality of spaced apart electrical contacts to strike the microchannel plate. The one or more electronics are configured to receive the information indicative of the pattern at which the electrons strike the microchannel plate and generate an image in the pattern at which the electrons strike the microchannel plate.

The present disclosure is directed in certain embodiments to methods for creating a semiconductor detector to detect light that may be of a predetermined wavelength or within a predetermined range of wavelengths. For example, suitable ranges of wavelengths include light within the visible spectrum, or the mid-infrared spectrum, or the long wave-length infrared spectrum. In one embodiment, a method is provided that uses high quality micro-size semiconductor crystals grown on dissimilar substrate and therefore enables quantum detection with high operation temperature, high detectivity and fast speed. Where used herein the term “mid-IR” refers to electromagnetic wavelengths in a range of from about 2 micrometers to about 12 micrometers. The semiconductor detector methods may be used in devices in fields including, but not limited to, environmental monitoring, medical diagnosis, surveillance, night vision goggles and missile defense. In one embodiment, the detector could solve a long-lasting problem of fabricating high quality detectors on dissimilar substrate and therefore enable large format detectors to be fabricated on large and flexible substrates.

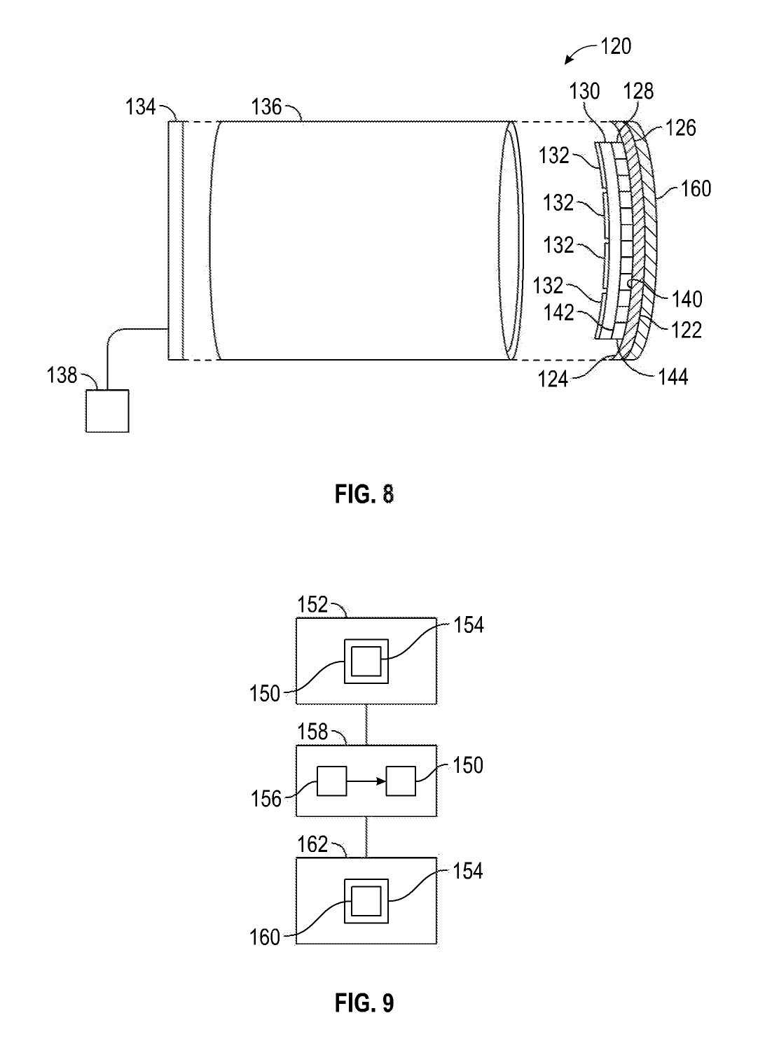

To create the semiconductor device, a substrate having at least one surface is provided. A layer of polycrystalline material is attached to the substrate. For example, the polycrystalline material may be grown on the substrate, or may be grown separately and then attached to the substrate. Once the polycrystalline material is attached to the substrate, the polycrystalline material may be sensitized to enhance or create the polycrystalline material's ability to receive and interact with the light. Thereafter, one or more electrical contacts can be applied to the polycrystalline material to create a photo conductive device in which changes in light interacting with the polycrystalline material changes the polycrystalline material's resistance to conducting electricity. Alternatively, a junction (either p-n or Schottky) can be applied to the polycrystalline material to create a photovoltaic device in which light interacting with the polycrystalline material creates a charge that can be detected at the junction. In some embodiments, the semiconductor device may emulate a bio-compound eye, specifically where the polycrystalline material is attached to a curved substrate, as described herein and shown in FIGS. 8 and 10.

In either case, the photoconductive or the photovoltaic device can be used separately to detect light. Or, multiples of the photoconductive or photovoltaic devices can be aggregated to create an array for detecting light. The array may be described in the attached materials as a “compound eye”. In one embodiment, mono-crystals from the polycrystalline material may form the photoconductive or photovoltaic device. In this embodiment, as described above, multiples of the photoconductive or photovoltaic devices may be aggregated to create the array for detecting light.

The substrate can be constructed in a variety of different manners and at a minimum is used to provide mechanical support for the polycrystalline material. The substrate can have a variety of shapes, such as planar, curved, or a combination of planar and curved portions. The substrate can be constructed of a monocrystalline or polycrystalline semiconductor material such as, but not limited to, silicon (e.g., monocrystalline silicon), glass, silica, quartz, sapphire, CaF₂, and other substrates commonly used by persons having ordinary skill in the art to construct photodetectors. The substrate can be rigid or flexible, and may be provided with a first with a first surface and a second surface opposite the first surface. In certain applications, it may be advantageous for the substrate to be able to pass light of the wavelengths or wavelength ranges to be detected by the photovoltaic or photoconductive device. For example, in certain embodiments the junction or electrical contacts may block the passage of light and in this case the substrate may be constructed to pass the light to the polycrystalline material.

Application of the polycrystalline material to the substrate may be accomplished in a variety of manners. For example, the polycrystalline material may be grown on the substrate using various methodologies such as chemical deposition or physical deposition, or the polycrystalline material can be adhered or otherwise attached to the substrate. In some embodiments, the polycrystalline material may be formed from group IV-VI semiconductor material, including, but not limited to, lead salt semiconductors such as PbSe, PbS, PbSnSe, PbTe, PbSnTe, PbSrSe, PbSrTe, PbEuSe, PbEuTe, PbCdSe, PbCdTe, and any lead salt containing a combination of two, three, four, or more Group IV and Group VI elements. Although the polycrystalline material is disclosed as being formed from group IV-VI semiconductor material, it will be understood that other semiconductor material may also be used to form the polycrystalline material.

As discussed above, the polycrystalline layer may be sensitized (for example as discussed below) to create or enhance the polycrystalline layer's ability to interact with light. This can be accomplished, for example, by annealing the polycrystalline layer in a predetermined atmosphere, such as oxygen or iodine. In one embodiment, annealing the polycrystalline material creates an insulating layer on an upper surface of the polycrystalline layer. The polycrystalline layer may have a plurality of individual microcrystals having boundary domains due to different orientations of the microcrystals, and in this case, the insulating layer may also be provided on the boundary domains separating the plurality of individual microcrystals.

In certain embodiments of the present disclosure, to create a photovoltaic device, one or more junction (p-n junction or Schottky contact) layers may be formed on a surface formed by the polycrystalline material. In this instance, the one or more junction layer may have a lower surface in contact with the insulating layer and an upper surface opposite the lower surface. Where the junction is a p-n junction, the junction may be created by doping, diffusion, ion implantation, or the p-n junction may be grown epitaxially. Where the junction is a Schottky contact, such as a Pb layer, the Schottky contact may be deposited on the surface formed by the polycrystalline material. The Schottky contact may then be annealed under a predetermined atmosphere, such as nitrogen. The one or more electrical contact layers may be connected to the junction and/or the substrate.

In certain embodiments of the present disclosure, to create a photoconductive device, two or more electrical contact layers, spaced apart from one another, may be attached to two or more surfaces formed by the polycrystalline material such that the electrical contact layers are disposed on opposing ends of the polycrystalline material. For example, two spaced apart trenches may be formed (such as by etching) in the layer of polycrystalline material to receive the electrical contact layers.

In one embodiment, suitable for night vision applications, the semiconductor device is provided with a substrate. The substrate may have a first surface and a second surface opposite the first surface, where the second surface forms an outer surface of a convex curve of the substrate. A layer of polycrystalline material is attached to the first surface of the substrate which forms an inner surface of a concave curve of the substrate. The layer of polycrystalline material may be attached as described herein in reference to the semiconductor device. Once the polycrystalline material is attached to the substrate, the polycrystalline material may be sensitized, as described herein. A junction is applied to the layer of polycrystalline material on a surface opposite of the substrate. A plurality of electrical contacts may then be applied to the junction and/or a portion of the substrate, such that light interacting with the layer of polycrystalline material may cause certain of the plurality of electrical contacts to emit electrons. A vacuum tube may be connected to the substrate such that electrons emitted by the plurality of electrical contacts may pass through the vacuum tube. A microchannel plate may be connected to the vacuum tube, such that the emitted electrons strike the microchannel plate. One or more electronics may be electrically connected to the microchannel plate to interpret information generated by the microchannel plate relating to the emitted electrons.

As noted elsewhere herein, the substrate may be a curved substrate, the curved substrate being transparent to a predetermined set of wavelengths, for instance mid-wavelength infrared or long-wavelength infrared.

As noted above, the polycrystalline material may be formed from the group IV-VI semiconductor materials, or other semiconductor materials. Where the polycrystalline material is formed from group IV-VI semiconductor material, the sensitized layer of polycrystalline material may be sensitive to mid and long wavelength infrared radiation, enabling this embodiment to be used in night vision applications such as image intensification, active illumination, and thermal imaging, for example.

The substrate, may be placed at one end of a vacuum tube so that when light passes through the substrate, contacting the layer of polycrystalline material, the junction layer, and the plurality of electrical contacts, electrons are emitted through the vacuum tube to a microchannel plate which receives the electrons and generates information indicative of a pattern at which the electrons strike the microchannel plate. The one or more electronics may be configured to receive the information indicative of the pattern at which the electrons strike the microchannel plate and generate an image in the pattern at which the electrons strike the microchannel plate.

Embodiments suitable for night vision applications may also be suitable to perform passive detection, detecting mid to long wavelength infrared emissions, such as heat, from a passive subject. These embodiments may also be suitable for active detection, such as light detection and ranging (LIDAR).

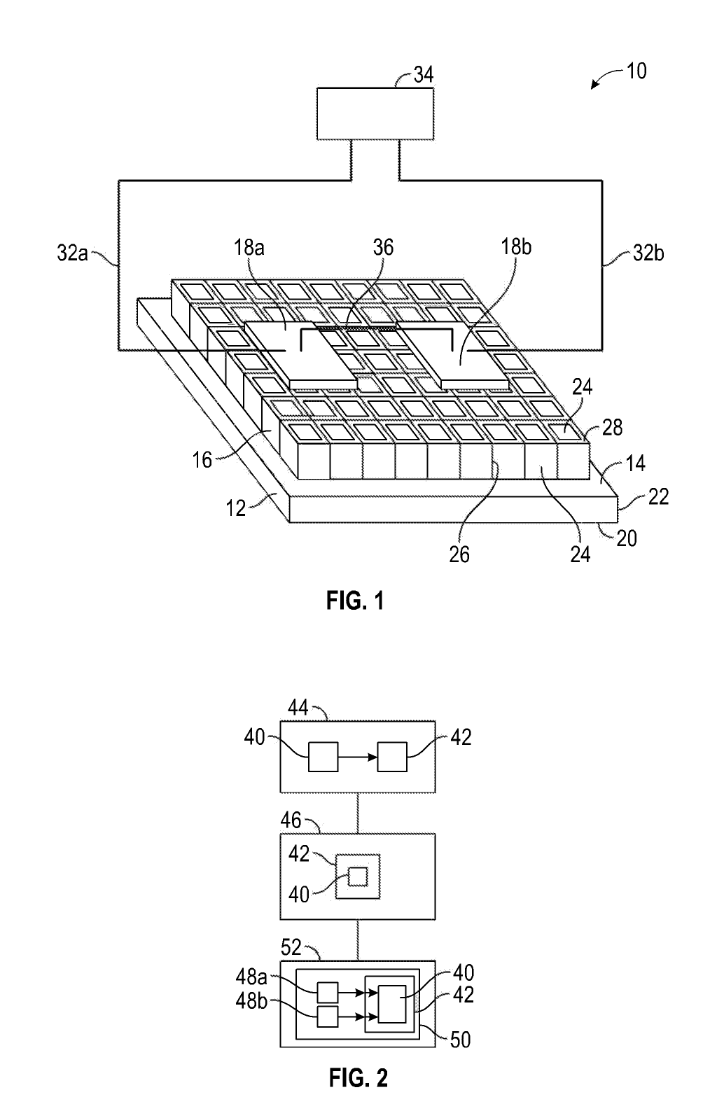

Referring now to the figures, shown in FIG. 1 is an embodiment of a photoconductive device 10. The photoconductive device 10 includes a substrate 12 having a surface 14, a layer of polycrystalline material 16 applied to the surface 14 of the substrate 12, and two or more spaced apart electrical contacts 18a and 18b connected to the layer of polycrystalline material 16. As noted above, the layer of polycrystalline material 16 may be formed from a IV-VI semiconductor material, such as a lead salt semiconductor material. The substrate 12 may be any substrate material discussed herein, including, but not limited to: a silicon substrate, such as a monocrystalline silicon substrate; a silicon micro-lens; a mid-infrared transparent substrate; an infrared transparent substrate; a substrate transparent to light in a visible portion of the light spectrum; a polyimide substrate developed for solar cell applications; a monocrystalline semiconductor material; or other monocrystalline or polycrystalline substrates dissimilar to the layer of polycrystalline material 16. The substrate 12 can be constructed of a monocrystalline or polycrystalline semiconductor material such as, but not limited to, silicon (e.g., monocrystalline silicon), glass, silica, quartz, sapphire, CaF₂, amorphous materials such as glass, conductive transparent (in visible) materials such as fluorine doped Tin Oxide, or Indium Tin Oxide, metals such as gold and other substrates commonly used by persons having ordinary skill in the art to construct photodetectors. In some embodiments, the surface 14 may be a first surface 14, such that the substrate 12 has the first surface 14, a second surface 20 opposite the first surface 14, and a thickness 22 extending between the first surface 14 and the second surface 20. In some other embodiments, substrate 12 may be constructed as a cylinder and the surface 14 may be a single surface defining the substrate 12 between a first end and a second end.

The substrate 12 may be constructed in a variety of different manners and may have a variety of shapes, such as planar, curved, or a combination of planar and curved portions. The substrate 12 can be rigid or flexible. As noted above, in some embodiments, the substrate 12 may be able to pass light of the wavelengths or wavelength ranges to be detected by the photoconductive device 10.

The polycrystalline material 16 may be grown on the surface 14 of the substrate 12, as will be explained below in more detail. As noted above, in certain embodiments where the layer of polycrystalline material 16 is formed from a IV-VI semiconductor material, the layer of polycrystalline material 16 may be a lead salt chosen from a group comprising PbSe, PbS, PbSnSe, PbTe, PbSnTe, PbSrSe, PbSrTe, PbEuSe, PbEuTe, PbCdSe, PbCdTe, and any lead salt containing a combination of two, three, four, or more Group IV and Group VI elements and any other lead salt described elsewhere herein. As will be described in more detail below, the layer of polycrystalline material 16 may be sensitized to enhance or create an ability to receive and interact with light. The layer of polycrystalline material 16 may be sensitized by annealing the polycrystalline material 16 under a predetermined atmosphere. In some embodiments, the predetermined atmosphere may be an Iodine atmosphere follow by an Oxygen atmosphere.

One embodiment of a sensitization method which can be used in the presently disclosed inventive concepts is hereby described:

Before heat-sensitization, the layers of polycrystalline material (semiconductor films) obtained from the above procedures are stored in vacuum vessels for 12-24 hours. Then the films are sensitized by heating for about 10-60 minutes at the temperatures between 420° C. and 450° C. followed by iodine vapor carried by nitrogen gas or oxygen with a 5-50 sccm flow at 350° C.-390° C. for 10-30 min. this sensitization results in a more stable and requested resistivity which increases 3 orders of magnitude during the exposure period and remains constant thereafter. In one embodiment, the sensitization process uses pure oxygen in a first step to improve the crystal quality. The O₂ annealing temperature in certain embodiments is in a range of about 375° C. to about 385° C., for example about 380° C., and annealing time, in certain embodiments, is in a range of about 20 min to about 30 min, for example about 25 min. The annealing time can vary depend on the size of the crystallites. After this step, I₂ is introduced for about 3 min to about 10 min, for example about 5 min, to sensitize the material. Again, the optimized temperature for I₂ annealing may vary depending on the size of the crystallites and the surface conditions after the O₂ annealing step. The temperature for the iodine step may be in a range of about 375° C. to about 385° C., for example about 380° C.

In one embodiment, the layer of polycrystalline material is a lead salt film, and the sensitization method includes exposing a lead salt-coated substrate to an oxygen atmosphere or nitrogen atmosphere or an oxygen-nitrogen atmosphere for a duration of time in a range of about 10 minutes to about 30 minutes at a temperature in a range of about 350° C. to about 390° C., followed by a step of exposing the lead salt-coated substrate to an iodine vapor for a duration of time in a range of about 3 minutes to about 10 minutes at a temperature in a range of about 350° C. to about 390° C., forming a sensitized lead salt-coated substrate.

More particularly, in the method the lead salt-coated substrate may be exposed to the oxygen atmosphere or nitrogen atmosphere or oxygen-nitrogen atmosphere for a duration of time in a range of about 20 minutes to about 30 minutes at a temperature in a range of about 375° C. to about 385° C., followed by the step of exposing the lead salt-coated substrate to the iodine vapor for a duration of time in a range of about 3 minutes to about 10 minutes at a temperature in a range of about 375° C. to about 385° C. Even more particularly, in the method, the lead salt-coated substrate is exposed to the oxygen atmosphere or nitrogen atmosphere or oxygen-nitrogen atmosphere for about 25 minutes at a temperature of about 380° C., followed by the step of exposing the lead salt-coated substrate to the iodine vapor for about 5 minutes at a temperature of about 380° C. A detector formed using the polycrystalline material (film) sensitized with this method in certain embodiments has a detectivity of at least 1.0×10¹⁰ cm·Hz^{1/2}·W⁻¹ when uncooled, a detectivity of at least 1.5×cm·Hz^{1/2}·W⁻¹ when uncooled, a detectivity of at least 2.0×10¹⁰ cm·Hz^{1/2}·W⁻¹ when uncooled, a detectivity of at least 2.5×10¹⁰ cm·Hz^{1/2}·W⁻¹ when uncooled, or a detectivity of at least 2.8×10¹⁰ cm·Hz^{1/2}·W⁻¹ when uncooled.

The layer of polycrystalline material 16, grown on the substrate 12, may be formed from a plurality of microcrystals 24. Each of the plurality of microcrystals 24 may have one or more junctions 26 at the intersection and/or contact point of two or more of the plurality of microcrystals 24. In some embodiments, where the photoconductive device 10 is used as a compound eye or in imaging applications, each of the microcrystals 24 (which may be referred to herein as a first crystal or second crystal) may act as an individual pixel. In some of these embodiments, each of the microcrystals 24 may be connected to one of the two or more spaced apart electrical contacts 18a and 18b to act as individual pixels. In some other embodiments, multiple of the plurality of microcrystals 24 (which may be referred to herein as a set of first crystals or a set of second crystals) may share and be connected to a single one of the two or more spaced apart electrodes 18a and 18b and cooperate to act as a pixel.

The one or more junctions 26 may be formed in part by insulating oxide layers 28 between boundary layers or junctions 26 separating each of the microcrystals 24 from each of the other contacted plurality of microcrystals 24. The microcrystals 24 may be constructed of PbSe, and the insulating oxide may be selected from the following materials: PbOₓ, PbSe₁₋ₓOₓ (x=0-1). The insulating oxide layers 28 may be formed during an annealing process. In some embodiments, the annealing process is performed under an Oxygen atmosphere, where the layer of polycrystalline material 16 is a Pb-salt material. In some embodiments the insulating oxide layers 28 at the junctions 26 form an insulating and passivation layer preventing cross talk between the individual microcrystals 24 (or groups of microcrystals) of the plurality of microcrystals.

In some embodiments, as shown in FIG. 1, each of the two or more spaced apart electrical contacts 18a and 18b are optionally connected via lead wires (wire contacts) 32a and 32b, respectively to an electrical system 34. The two or more electrical contacts 18a and 18b may be electrodes. As previously noted above, in some embodiments, each of the two or more spaced apart electrical contacts 18a and 18b may be connected to a single microcrystal 24. In some embodiments, as shown in FIG. 1, the each of the two or more spaced apart electrical contacts 18a and 18b may be electrically coupled to multiple of the plurality of microcrystals 24. Although FIG. 1 includes two electrical contacts 18a and 18b connecting to a portion of the plurality of microcrystals 24, it will be understood by one skilled in the art that the photoconductive device 10 may have any number of spaced apart electrical contacts, such as electrical contacts 18a and 18b. For example, in at least some embodiments, each of the plurality of microcrystals 24 may be electrically coupled to an electrical contact. In some embodiments, the electrical contacts 18a and 18b are formed from a thin layer of Au, a layer of Au mesh, or any other electrode material capable of registering a change in resistance to conducting electricity due to changes in light interacting with the layer of polycrystalline material 16. In some embodiments, certain of the two or more spaced apart electrical contacts 18a and 18b may be electrically coupled to one or more other spaced apart electrical contacts via a lead such as lead 36.

In some embodiments, the electrical system 34 may be implemented as a readout integrated circuit (ROIC), electronics configured to receive information indicative of patterns in electron strikes, a computer system, or any other suitable electrical system 34 capable of receiving electrical signals, voltages, and/or information generated by the two or more spaced apart electrical contacts 18. Where implemented as a computer system, the electrical system 34 may include at least one processor capable of executing processor executable instructions, a non-transitory processor readable medium capable of storing processor executable instructions, an input device, an output device, and a communications device, all of which may be partially or completely network-based or cloud based, and may not necessarily be located in a single physical location.

Where implemented as a computer system, the processor of the electrical system 34 can be implemented as a single processor or multiple processors working together to execute processor executable instructions including the logic described herein. Exemplary embodiments of the processor may include a digital signal processor (DSP), a central processing unit (CPU), a field programmable gate array (FPGA), a microprocessor, a multi-core processor, a quantum processor, application-specific integrated circuit (ASIC), a graphics processing unit (GPU), a visual processing unit (VPU) and combinations thereof. The processor is operably coupled with the non-transitory processor readable medium via a path which can be implemented as a data bus allowing bi-directional communication between the processor and the non-transitory processor readable medium, for example. The processor is capable of communicating with the input device and with the output device via additional paths, which may be one or more data busses, for example. The processor may be further capable of interfacing and/or bi-directionally communicating with a network using the communications device, such as by exchanging electronic, digital, analogue, and/or optical signals via one or more physical, virtual, or logical ports using any desired network protocol such as TCP/IP, for example. It is to be understood that in certain embodiments using more than one processor, multiple processors may be located remotely from one another, located in the same location, or comprising a unitary multi-core processor. The processor is capable of reading and/or executing processor executable code stored in the one or more non-transitory processor readable medium and/or of creating, manipulating, altering, and storing computer data structures into the one or more non-transitory processor readable medium.

Where implemented as a computer system, the non-transitory processor readable medium of the electrical system 34 may store a program having processor executable instructions configured to receive and interpret electrical signals, voltages, and/or information received from the two or more spaced apart electrical contacts 18. The processor executable instructions may also be configured to provide signal processing to take advantage of biomimetic compound eyes, where the photoconductive device 10 is implemented as a compound eye, for example when implemented with other photoconductive devices 10 in an array. The non-transitory processor readable medium may be implemented as any type of memory, such as random access memory (RAM), a CD-ROM, a hard drive, a solid state drive, a flash drive, a memory card, a DVD-ROM, a floppy disk, an optical drive, and combinations thereof, for example. While the non-transitory processor readable medium may be located in the same physical location as the processor, the non-transitory processor readable medium may also be located remotely from the processor and may communicate with the processor via the network. Additionally, when more than one non-transitory processor readable medium is used, one or more non-transitory processor readable medium may be located in the same physical location as the processor, and one or more non-transitory processor readable medium may be located in a remote physical location from the processor. The physical location of the non-transitory processor readable medium can be varied, and the non-transitory processor readable medium may be implemented as a “cloud memory” i.e., one or more non-transitory processor readable medium which is partially, or completely based on or accessed using the network, for example. Further, the one or more processor may not communicate directly with the non-transitory processor readable medium, but may communicate with another processor communicating with the non-transitory processor readable medium over the network, for example. In some exemplary embodiments, the processor may include a first processor communicating with a second processor executing processor executable instructions including the word recognition and media insertion program over the network. The second processor may be part of a computer station, or may be a part of a separate computer system or server configured to communicate with the computer system over the network or otherwise operably coupled with the computer system, for example.

Where the electrical system 34 is implemented as a computer system, the input device may pass data to the processor, and may be implemented as a keyboard, a mouse, a touch-screen, a camera, a cellular phone, a tablet, a smart phone, a personal digital assistant (PDA), a microphone, a network adapter, the photoconductive device 10, and combinations thereof, for example. The input device may also be implemented as a stylus, a mouse, a trackball, and combinations thereof, for example. The input device may be located in the same physical location as the processor, or may be remotely located and/or partially or completely network-based.

Where implemented as a computer system, the output device of the electrical system 34 passes information from the processor to a user in a user perceivable format. For example, the output device can be implemented as a server, a computer monitor, a cell phone, a smartphone, a tablet, a speaker, a website, a PDA, a fax, a printer, a projector, a laptop monitor, a night vision device, a display of a night vision device, and combinations thereof. The term “pass” as used herein may refer to either push technology, or to pull technology, and to combinations thereof. The output device can be physically co-located with the processor, or can be located remotely from the processor, and may be partially or completely network based (e.g., a website). The output device communicates with the processor. As used herein the term “user” is not limited to a human, and may comprise a human, a computer, a host system, a smart phone, a tablet, and combinations thereof, for example.

Referring now to FIG. 2, therein shown is one embodiment of a method for creating the photoconductive device 10. The method is performed by applying a layer of polycrystalline material 40 to a surface of a substrate 42, as depicted by block 44. The polycrystalline material 40 may be sensitized, as indicated by block 46, to enhance or create the polycrystalline material's 40 ability to receive and interact with light. The method may further be performed by applying two or more spaced apart electrical contacts 48a and 48b to the polycrystalline material 40 to create a photoconductive device 50 in which changes in light interacting with the polycrystalline material 40 changes the polycrystalline material's 40 resistance to conducting electricity, as indicated by block 52. In some embodiments, the photoconductive device 50 may be similar to or the same as the photoconductive device 10.

In some embodiments, applying the polycrystalline material 40 to the surface of the substrate 42, as indicated by block 44, may be performed by growing a plurality of microcrystals on the surface of the substrate 42 (as explained in further detail below). In some embodiments, the plurality of microcrystals (such as microcrystals 24 shown in FIG. 1), forming the polycrystalline material 40, may be a IV-VI semiconductor material, such as a lead salt semiconductor. In some embodiments, the lead salt semiconductor is chosen from a group comprising PbSe, PbS, PbSnSe, PbTe, PbSnTe PbSrSe, PbSrTe, PbEuSe, PbEuTe, PbCdSe, PbCdTe, and any lead salt containing a combination of two, three, four, or more Group IV and Group VI elements. The plurality of microcrystals may have boundary domains, due to different orientations of the microcrystals, forming divisions between the plurality of microcrystals. In some embodiments, the plurality of microcrystals, forming the layer of polycrystalline material 40 may be about 1 μm in size and about 1 μm in thickness. It should be noted that the shape of the microcrystal (crystallite) is cubic or near-cubic. The “size” of such crystallite (e.g., length, width or height) could range from 100 nm to a few micro-meters, and common sizes are in a range from about 100 nm to about 1000 nm. The size, however, can be controlled using known techniques, to grow one-dimensional column-like crystals, in which the crystallite has a square base with a length and/or width in the range of about 1 nm to about 2000 nm and a height in a range from about 1 nm to about 10,000 nm (10 mm). In principle, height can be even higher than than 10 mm. In some other embodiments, the plurality of microcrystals forming the layer of polycrystalline material may be about 100 nm or about 500 nm in size.

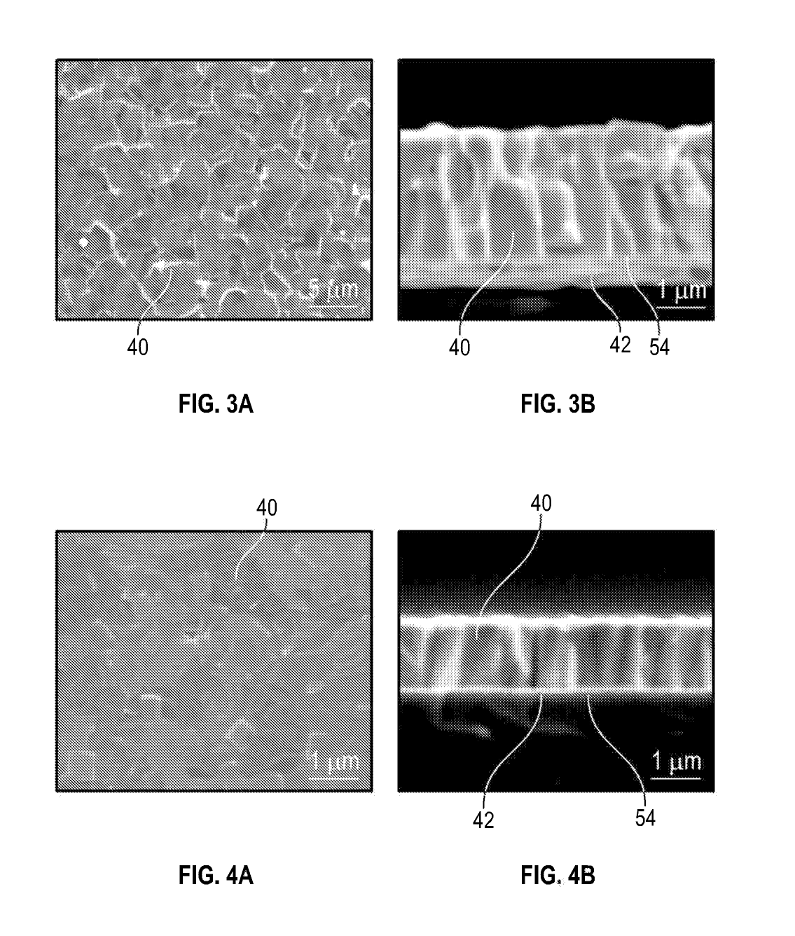

In some embodiments the layer of polycrystalline material 40 may be applied to the substrate 42 by chemical bath deposition (CBD). In embodiments where the layer of polycrystalline material 40 is applied to the substrate 42 via CBD, the pumping intensity on CBD may increase photoluminescence sensitivity. An example of the layer of polycrystalline material 40 applied to the substrate 42 by CBD is shown in FIGS. 3a and 3b in a scanning electron microscopy image. As shown in FIG. 3b, a thin seed layer 54 is grown using chemical or physical deposition. In this embodiment, certain of the plurality of microcrystals (such as microcrystals 24) of the layer of polycrystalline material 40 have (100) orientation despite the substrate 42, a Si substrate, having (111) orientation. Further, there is no boundary domain in a vertical direction, but rather solely in a horizontal direction. As such, the layer of polycrystalline material 40 forms a closely packed micro-crystal array.

In some embodiments, the layer of polycrystalline material 40 may be applied to the substrate 42 via molecular beam epitaxy, as shown in FIGS. 4a and 4b. Similar to the process shown in FIGS. 3a and 3b, the thermal deposition process may include the thin seed layer 54 and no boundary domains in the vertical direction.

With either application process, in certain embodiments, each microcrystal of the plurality of microcrystals forming the layer of polycrystalline material 40 may have a width in a range of from about 50 nm to about 1 μm (in the horizontal direction). In some embodiments, each microcrystal of the plurality of microcrystals may have a height in a range of from about 1 μm to about 10 μm (in the vertical direction), such that the polycrystalline material 40 formed from the microcrystals has a thickness in a range of from about 50 nm to about 1 μm to about 10 μm.

In some embodiments, where the substrate 42 is non-planar, such as is shown in FIGS. 8 and 10, the layer of polycrystalline material 40 may be applied to the substrate 42 by CBD, for example. In the embodiments shown, the substrate 42 comprises a bed of Si nano-wires upon which the layer of polycrystalline material 40 is disposed. Other non-planar substrates 42 may also include, but are not limited to, Au wire, Si lenses, and other suitable non-planar dissimilar substrates.

Referring again to FIG. 2, in some embodiments, sensitizing the polycrystalline material 40, as indicated by block 46, may be performed by annealing the polycrystalline material 40 under a predetermined atmosphere as discussed above. The predetermined atmosphere, in some embodiments, may be an Iodine atmosphere followed by an Oxygen atmosphere. As previously discussed, in at least some embodiments, annealing the polycrystalline material 40 may create the insulating oxide layer 28 on an upper surface of the layer of polycrystalline material 40, opposite the surface contacting the substrate 42. Additionally, the sensitizing process may form the insulating layer at the boundary domains of the plurality of microcrystals. As noted above, the insulating layer may separate individual microcrystals 24 of the plurality of microcrystals 24 within the layer of polycrystalline material 40. The insulating layer at the boundary domains may prevent cross talk and/or interference between individual microcrystals of the plurality of microcrystals when interacting with light or conducting electricity. In some embodiments, the layer of polycrystalline material 40 may be sensitized to mid and long wavelength infrared radiation. In these embodiments, the photoconductive device may be used in night vision applications such as image intensification, active illumination, and thermal imaging, for example. In some embodiments, where the layer of polycrystalline material 40 is applied to the substrate 42 by MBE and annealed in high-purity oxygen, photoluminescence (PL) intensity may be increased, rather than suppressed, after O₂ annealing. The oxygen may serve as a defect passivator. Annealing in an Iodine atmosphere may serve to increase photo-response.

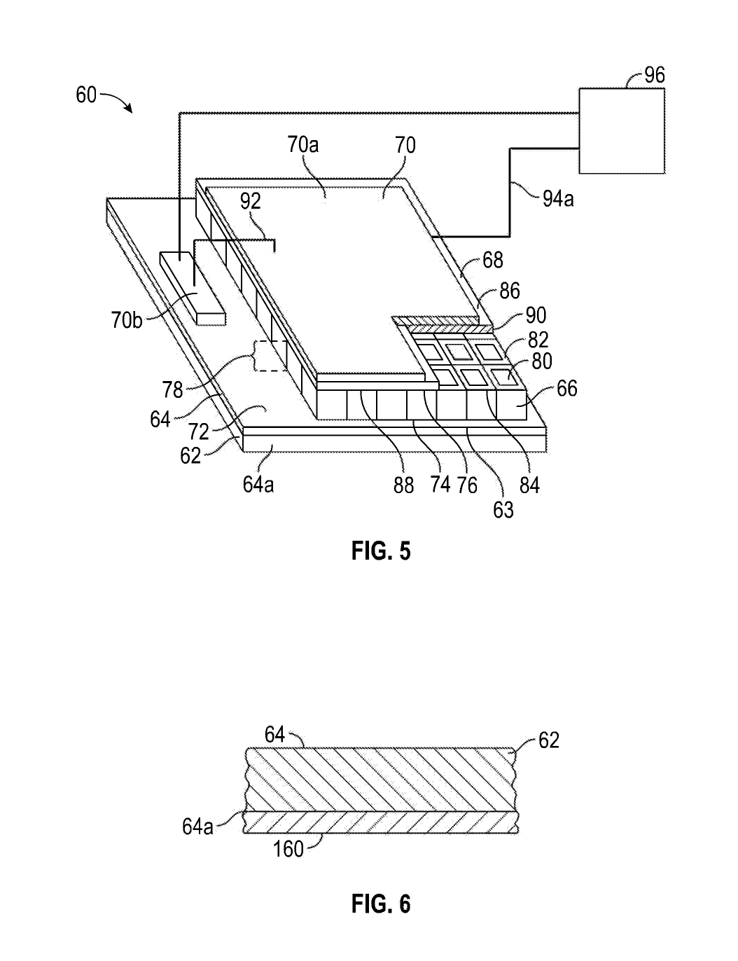

Referring now to FIG. 5, shown therein is an embodiment of a photovoltaic device 60 constructed in accordance with the presently disclosed inventive concepts. The photovoltaic device 60 includes a substrate 62 having an upper surface 64, a lower surface 64a, a layer of polycrystalline material 66 applied to the upper surface 64 of the substrate 62, a junction layer 68 applied to the layer of polycrystalline material 66, and two or more spaced apart electrical contacts 70a and 70b connected to the junction layer 68 and the substrate 62. Although shown as a single photovoltaic device 60, it should be understood by one skilled in the art that the photovoltaic device 60 may be implemented in cooperation with a plurality of photovoltaic devices 60 to form a photovoltaic array, such as an n×n array having dimensions between about 5 μm=5 μm to about 2 cm×2 cm, with each of the photovoltaic devices 60 functioning in cooperation with the others. In some embodiments, each photovoltaic device 60 within the array may act as a 40 μm×40 μm detector, although it should be understood that the length and width of the photovoltaic device 60 may vary.

In some embodiments, the substrate 62 may be implemented similar to the substrate 12. In some embodiments, the substrate is at least partially transparent to certain wavelengths of the spectrum of light, such as, but not limited to, mid IR wavelengths as defined herein. As shown, in some embodiments, the substrate 62 may be a mid-infrared transparent substrate having a mid-infrared transparent ohmic contact 63 on the upper surface 64 of the substrate 62. In these embodiments, the layer of polycrystalline material 66 may be applied to an upper surface 72 of the mid-infrared transparent ohmic contact 63. Although described as transparent to the mid-infrared section of the spectrum of light, it should be understood by one skilled in the art that the substrate 62 and the transparent ohmic contact 63 may be formed from material transparent to any section of the spectrum of light, such as a long-wave section of the spectrum of light, a visible section of the spectrum of light, or any other section of the spectrum of light. Similar to the substrate 12, the substrate 62 may be rigid or flexible, and may be planar or non-planar in configuration.

The layer of polycrystalline material 66 may be implemented similar to the layer of polycrystalline material 16 described above. The layer of polycrystalline material 66 may have a first surface 74 and a second surface 76 opposite the first surface 74. The first surface 74 may be applied to the substrate 62 and the second surface 76 extending a distance above the substrate 62. The layer of polycrystalline material 66 has a thickness 78 between the first surface 74 and the second surface 76. In some embodiments, the thickness 78 is in a range of from about 1 μm to about 10 μm. However, it will be understood by one skilled in the art that the thickness 78 may be any suitable thickness capable of being formed during the application of the layer of polycrystalline material 66 to the substrate 62. The layer of polycrystalline material 66, grown on the substrate 62, comprises a plurality of microcrystals 80. In certain embodiments, each microcrystal of the plurality of microcrystals forming the layer of polycrystalline material 66 may have a width in a range of from about 50 nm to about 1 μm (in the horizontal direction). In some embodiments, each microcrystal of the plurality of microcrystals may have a height in a range of from about 1 μm to about 10 μm (in the vertical direction), such that the polycrystalline material 66 formed from the microcrystals has a thickness in a range of from about 50 nm to about 1 μm to about 10 μm.

As noted above, in some embodiments, the layer of polycrystalline material 66 may be formed from a IV-VI semiconductor material, such as a lead salt semiconductor material, such as PbSe, PbS, PbSnSe, PbTe, PbSnTe, PbSrSe, PbSrTe, PbEuSe, PbEuTe, PbCdSe, PbCdTe, or any lead salt containing a combination of two, three, four, or more Group IV and Group VI elements. The layer of polycrystalline material 66 may be sensitized to enhance or create an ability to receive and interact with light. For example, the layer of polycrystalline material 66 may be sensitized by annealing the layer of polycrystalline material 66 under a predetermined atmosphere as described elsewhere herein. In some embodiments, the predetermined atmosphere may be an iodine-containing atmosphere follow by an oxygen-containing atmosphere. Each of the plurality of microcrystals 80 may have one or more junctions 82 at the intersection and/or contact point of two or more of the plurality of microcrystals 80. The one or more junctions 82 may be formed in part by an insulating oxide layer 84 between the one or more junctions 82 of the plurality of microcrystals 80.

The junction layer 68 is applied to the second surface 76 of the layer of polycrystalline material 66 opposite to the first surface 74 in contact with the substrate 62. The junction layer 68 may enable changes in light interacting with the layer of polycrystalline material 66 to create a change at the junction layer 68. In some embodiments, the junction layer 68 may block the passage of light, in these embodiments, the substrate 62 may be formed from a material capable of passing light to the layer of polycrystalline material 66. The junction layer 68 may be a p-n junction or Schottky contact and may be formed on the second surface 76 of the polycrystalline material 66. The junction layer 68 has an upper surface 86, a lower surface 88, and a thickness 90 extending between the upper surface 86 and the lower surface 88. The lower surface 88 of the junction layer 68 is in contact with the insulating oxide layer 84 formed on the second surface 76 of the layer of polycrystalline material 66. Where the junction layer 68 is a p-n junction, the junction layer 68 may be created by doping, diffusion, ion implantation, grown epitaxially, or any other suitable manner of applying the junction layer 68 to the second surface 76 of the layer of polycrystalline material 66. Where the junction layer 68 is a Schottky contact, such as a Pb layer, the Schottky contact may be deposited on the second surface 76 of the layer of polycrystalline material 66. The junction layer 68, implemented as the Schottky contact, may be annealed, after application to the second surface 76, under a predetermined atmosphere such as Nitrogen. In some embodiments, the junction layer 68 may be a Pb layer deposited and annealed around 200° C. and the Nitrogen atmosphere may be an N₂ atmosphere. In other embodiments, the junction layer 68 may be deposited and annealed at a temperature around 240° C. under an N₂ atmosphere. The interface, annealing may result in (PbSe)Oₓ+P_{b}→lead rich n-PbSe+PbOₓ. The PbOₓ may then be removed by polishing. A thin layer of Au may then be deposited on top of the junction layer 68 for an electrical contact.

The two or more spaced apart electrical contacts 70a and 70b as shown, may be positioned where electrical contact 70a is connected to the junction layer 68, and electrical contact 70b is connected to the upper surface 72 of the mid-infrared transparent ohmic contact 63 disposed over substrate 62. In these embodiments, the two or more spaced apart electrical contacts 70a and 70b may be electrically connected via a lead 92, or any other suitable electrical connection. In some embodiments, the electrical contacts 70a and 70b may be connected via first and second leads 94a and 94b, respectively, to an electrical system 96. The two or more spaced apart electrical contacts 70a and 70b may be implemented in a manner similar to the two or more spaced apart electrical contacts 18a and 18b (FIG. 1). Further, the electrical contacts 70a and 70b may be implemented similarly or differently from one another. For example, in some embodiments, the electrical contact 70a may be constructed of a thin layer of Au, while the electrical contact 70b may be constructed of a thin layer of Au mesh. In some embodiments, the electrical contact 70a may act as an anode, while the electrical contact 70b may act as a cathode, and vice versa. Shown in FIG. 6 is an alternate embodiment of the substrate 62 of photovoltaic device 60, wherein the lower surface 64a of substrate 62 has an antireflective coating 160 disposed thereon, as discussed in further detail below.

The electrical system 96 may be implemented similarly or the same as the electrical system 34 such as a readout integrated circuit (ROIC), electronics configured to receive information indicative of patterns in electron strikes, a computer system, or any other suitable electrical system 96 capable of receiving electrical signals, voltages, and/or information generated by the two or more spaced apart electrical contacts 70.

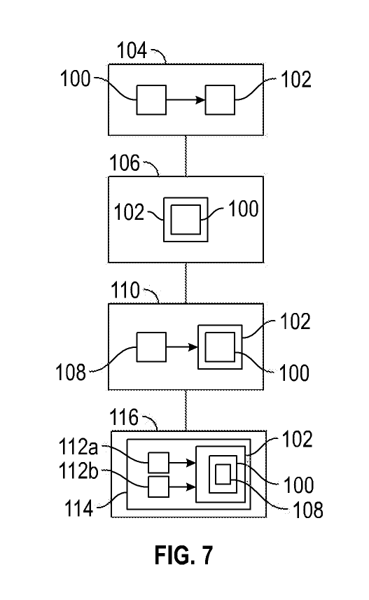

Referring now to FIG. 7, therein shown is one embodiment of a method for creating the photovoltaic device 60. The method is performed by applying a layer of polycrystalline material 100 to a surface of a substrate 102, as indicated by block 104. The layer of polycrystalline material 100 is sensitized (in a manner similar to the sensitization method described elsewhere herein) to enhance or create in the layer of polycrystalline material 100 an ability to receive and interact with light, as indicated by block 106. The method is further performed by applying a junction layer 108 to the layer of polycrystalline material 100 to enable changes in light interacting with the layer of polycrystalline material 100 to create a change at the junction layer 108, as indicated by block 110. Two or more spaced apart electrical contacts 112a and 112b are applied to the layer of polycrystalline material 100 and the substrate 102 to create a photovoltaic device 114, as indicated by block 116. The photovoltaic device 114 may generate a voltage or electrical current based on changes in light interacting with the layer of polycrystalline material 100 and the junction layer 108.

Similar to the method described in FIG. 2, the layer of polycrystalline material 100 may be grown using a IV-VI semiconductor material, as discussed above, such as a lead salt semiconductor. The layer of polycrystalline material 100 may be sensitized via annealing the layer of polycrystalline material 100 under a predetermined atmosphere, such as Iodine followed by Oxygen, for example as described previously, or other suitable methods. The junction layer 108 may be applied by depositing a Schottky contact layer, such as a Pb layer and then annealed under a Nitrogen atmosphere. In other embodiments, the junction layer may be applied by doping to create a p-n junction layer.

Referring now to FIG. 8, shown therein is one embodiment of a night vision semiconductor device 120 (a photodetector device) constructed in accordance with the presently disclosed inventive concepts. The night vision semiconductor device 120 includes a substrate 122 (constructed of any suitable substrate material as discussed elsewhere herein) having a first surface 124 and a second surface 126, a layer of polycrystalline material 128 applied to the first surface 124 of the substrate 122, a junction layer 130 applied to the layer of polycrystalline material 128, a plurality of spaced apart electrical contacts 132 connected to the junction layer 130, a microchannel plate 134, a vacuum tube 136 disposed between the plurality of spaced apart electrical contacts 132 and the microchannel plate 134, and one or more electronics 138 operably connected to the microchannel plate 134. The substrate 122 may be constructed of a material and have a shape similar to the substrate 12 or 62. However, the substrate 122, in this embodiment, is transparent to at least a portion of the spectrum of light, such as the mid-infrared or the long wave infrared sections of the spectrum of light. In the embodiment shown in FIG. 8 the substrate 122 has a curved configuration, wherein the first surface 124 forms a concave inner curve, and the second surface 126 forms a convex outer curve. Alternatively, in another embodiment, the substrate 122 may have a convex inner curve and a concave outer curve. Alternatively, in another embodiment, the substrate 122 may be substantially flat surface, or have any other surface which enables the photodetector device to operate in accordance with the presently disclosed inventive concepts. Second surface 126 optionally has an antireflective coating 160 disposed thereon.

The layer of polycrystalline material 128 may be applied to the inner curve of the first surface 124 and may be implemented similar to the layer of polycrystalline material 16 or 66. The layer of polycrystalline material 128 may be provided with a first surface 140 in contact with the substrate 122, a second surface 142 opposite the first surface 140, and a thickness 144 extending between the first and second surfaces 140 and 142. The layer of polycrystalline material 128 may be sensitized to enhance or create an ability to receive and interact with light as described elsewhere herein.

The junction layer 130 may be implemented similar to the junction layer 68. The junction layer 130 may be connected or applied to the second surface 142 of the layer of polycrystalline material 128 enabling changes in light interacting with the layer of polycrystalline material 128 to create changes at the junction layer 130, as described above.

The plurality of spaced apart electrical contacts 132 may be implemented similarly to or different from the spaced apart electrical contacts 18 and 70. In some embodiments, the spaced apart electrical contacts 132 may act to emit electrons indicative of the changes created at the junction layer 130 in response to light interacting with the layer of polycrystalline material 128.

The microchannel plate 134 may be configured to receive electrons emitted from the plurality of spaced apart electrical contacts 132 and generate information indicative of a pattern at which the electrons strike the microchannel plate.

The vacuum tube 136 may be devoid of air or other gasses and be configured to allow electrons emitted from the plurality of spaced apart electrical contacts 132 to strike the microchannel plate 134. The vacuum tube 136 may also be configured so as not to impede or alter the path of the electrons traveling therethrough.

The one or more electronics 138 may be implemented similarly to the electrical system 34 or 96. The one or more electronics 138 may be configured to receive the information indicative of the pattern at which the electrons strike the microchannel plate 134 and generate an image in the pattern at which the electrons strike the microchannel plate 134.

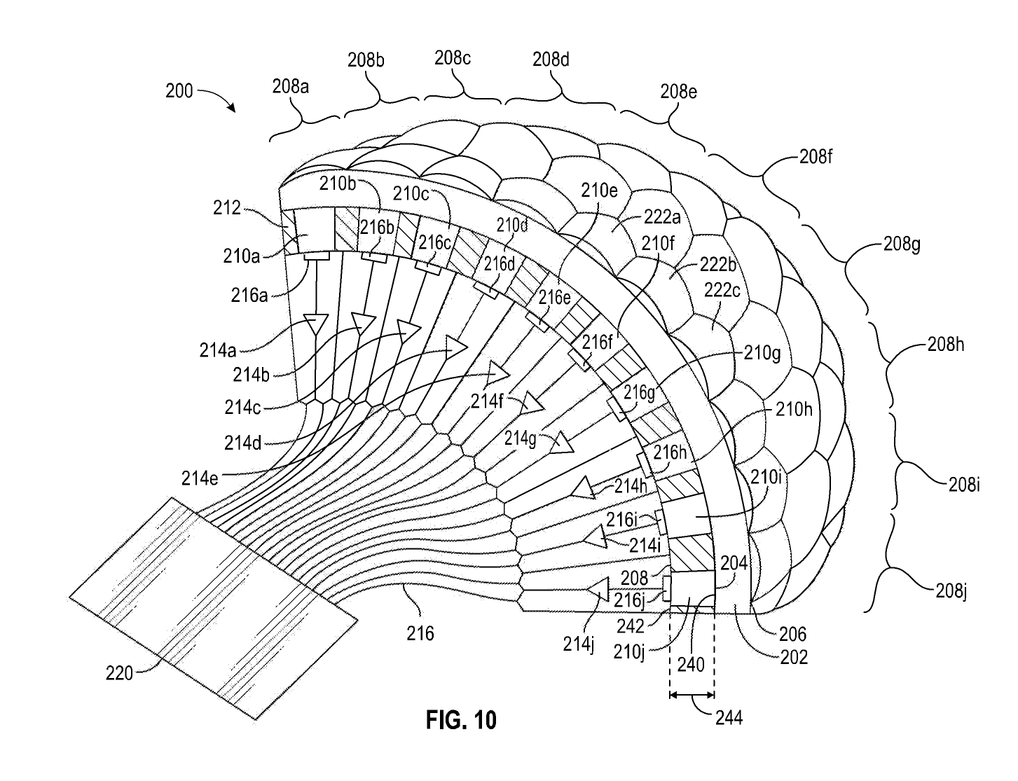

Referring now to FIG. 9, in some embodiments, an antireflective coating (ARC) may be used to improve performance in light emitters and detectors and solar cells. Nanostructured ARCS have broadband and omnidirectional properties. The ARCs may be formed from CaF₂, for example, and applied to the surface of a substrate, such as substrate 62 and 122. For example, in FIG. 6, in the above described embodiment of the photovoltaic device 60, where the substrate 62 is transparent to at least some wavelengths of light within the spectrum of light, the ARC 160 may be applied to the lower surface 64a opposite the surface 64 to which the layer of polycrystalline material 66 is applied. Similarly, in the embodiment of the night vision semiconductor device 120, described above, the ARC 160 may be applied to the second surface 126 of the substrate 122. In another embodiment, the ARC 160 may be formed on a layer of polycrystalline material, such as the layer of polycrystalline material 16, in embodiments where light may pass through the layer of polycrystalline material 16 without passing through the substrate 12 to which the layer of polycrystalline material 16 is applied. The CaF₂ ARC 160 may form blade-like CaF₂ nanostructure arrays to provide a contaminant free environment and a highly transparent coating in the infrared region of the spectrum of light. The CaF₂ coating, deposited in the manner to be described below, may form a uniform coating over a large area.

As shown in FIG. 9, the method may be performed by forming a vacuum chamber 150, as indicated by block 152. A substrate 154 may be placed within the vacuum chamber 150. A CaF₂ vapor 156 is introduced into the vacuum chamber 150, as indicated by block 158. The method is further performed by applying the CaF₂ vapor 156 to the substrate 154 to form a CaF₂ ARC coating 160, as indicated by block 162. The vacuum chamber 150 may be connected to a CaF₂ source, such as an effusion cell or CaF₂ source target. The CaF₂ source, in fluid communication with the vacuum chamber 150 may release the CaF₂ vapor at a predetermined time, or under predetermined conditions. In some embodiments, the vacuum chamber 150 may be connected to a target bombarding holder to generate physical vapor of CaF₂. The vacuum chamber 150 may be used to coat large area wafers or substrates, under high purity ambience. The vacuum chamber 150 may combine near-room temperature growth condition to prepare antireflective coatings to protect delicate optoelectronic devices from contamination or damage.

Applying the CaF₂ vapor to the substrate 154 may be performed by physical vapor deposition (PVD), molecular beam epitaxy (MBE), pulsed laser deposition (PLD), electron beam evaporation (EBE), or any other method suitable to apply CaF₂ vapor to a substrate 154 to create an antireflective coating. The substrate 154 may be implemented similar to the substrate 62 or 122, where the CaF₂ is applied to the substrate 154 on a surface opposite the surface to which the layer of polycrystalline material is applied. In some embodiments, the substrate 154 may be a layer of polycrystalline material, and may be implemented similar to the layer of polycrystalline material 16, 66, or 128.

The CaF₂ ARC 160, deposited onto the substrate 154, may be varied from 10 nm to 100 nm, or any other suitable thickness. The sub-wavelength size of the coating and the blade-like structures of the coating may create a gradient refractive index profile between air and the device surface. The profile may enhance coupling efficiency. The CaF₂ coating may be applied to a light emitting diode, where the CaF₂ coating is applied to the surface of the light emitting diode as an antireflective coating or an electric passivation layer. The CaF₂ coating may also be applied to the surface of a detector, a solar cell, a laser, a substrate in a night vision device, a photoconductive device, a photovoltaic device, or any other suitable device.

Referring now to FIG. 10, shown therein is a perspective view of one embodiment of a compound eye photodetector 200 constructed in accordance with the presently disclosed inventive concepts. The compound eye photodetector 200 includes a substrate 202 (constructed of any suitable substrate material as discussed elsewhere herein) having a first surface 204 and a second surface 206. The compound eye photodetector 200 also includes a plurality of photodetectors 208a-j which operate independently with respect to another and which are disposed about the first surface 204 so as to receive light that passes through the substrate 202, as will be discussed below. The photodetectors 208a-j can be formed by a layer of polycrystalline material 208 that is applied to the first surface 204 of the substrate 202. Each of the photodetectors 208a-j includes one or more cell diodes with each cell diode formed by a micro-size single crystal 210a-j surrounded by an insulating boundary 212 preventing cross talk between crystals 210a-j, and an electrical contact 214a-j including leads 216. The insulating boundary 212 can be an insulating oxide that can be formed using a sensitization process as described above.

When the photodetectors 208a-j are photoconductive devices, the electrical contacts 214 can be applied to the crystals 210. When the photodetectors 208a-j are photovoltaic devices, then the photodetectors 208a-j include a junction layer 216a-j between and in contact with the crystals 210a-j and the electrical contacts 214a-j. The leads 216 of the electrical contacts 214 can be electrically coupled to one or more electrical system 220 to supply electricity generated by the photodetectors 208a-j to the electrical system 220. The electrical system 220 can be constructed in a similar manner as the electrical system 34 that is described above. The compound eye photodetector 200 is also provided with a plurality of lenses 222 (three of which are labeled in FIG. 10 with the reference numerals 222a, 222b and 222c for purposes of clarity) applied to and spatially disposed about the second surface 206 of the substrate 202 with each lens 222 paired with at least one of the photodetectors 208a-j. The lenses 222 focus and supply light through a particular portion of the substrate 202 and onto one of the photodetectors 208a-j. The lenses 222 can be Si micro-lens.

The substrate 202 may be constructed of a material and have a shape similar to the substrate 122 which is transparent to at least a portion of the spectrum of light, such as the visible, mid-infrared or the long wave infrared sections of the spectrum of light. In the embodiment shown in FIG. 10 the substrate 202 has a curved configuration so that the photodetectors 208a-j and the lenses 222 are positioned in a non-parallel, substantially arcuate arrangement which increases the field of view of the compound eye photodetector 200. The first surface 204 may form a concave inner curve, and the second surface 206 may form a convex outer curve. Alternatively, in another embodiment, the substrate 202 may have a convex inner curve and a concave outer curve. Alternatively, in another embodiment, the substrate 202 may be a substantially flat surface, or have any other surface which enables the compound eye photodetector 200 to operate in accordance with the presently disclosed inventive concepts.

The layer of polycrystalline material 208 may be applied to the inner curve of the first surface 204 and may be implemented similar to the layer of polycrystalline material 16 or 66. The layer of polycrystalline material 208 may be provided with a first surface 240 in contact with the substrate 202, a second surface 242 opposite the first surface 240, and a thickness 244 extending between the first and second surfaces 240 and 242. The layer of polycrystalline material 208 may be sensitized to enhance or create an ability to receive and interact with light as described elsewhere herein.

Each of the photodetectors 208a-j can be operated as an individual pixel, enabling high density pixels without further processing. This offers a significant advantage for compact high resolution imaging applications. If limited by fabrication technique, each of the photodetectors 208a-j may use multiple cell diodes with each sharing one common contact and working in parallel as one pixel.

Although the preceding description has been described herein with reference to particular means, materials and embodiments, it is not intended to be limited to the particulars disclosed herein; rather, it extends to functionally equivalent structures, methods, and uses, such as are within the scope of the appended claims.

1. A method, comprising:
applying a layer of a polycrystalline IV-VI lead salt semiconductor material to a surface of a substrate, the layer of polycrystalline IV-VI lead salt semiconductor material comprising a plurality of microcrystals;
applying a junction layer to the layer of polycrystalline IV-VI lead salt semiconductor material to enable changes in light interacting with the layer of polycrystalline IV-VI lead salt semiconductor material to create a change at the junction layer; and
applying two or more spaced apart electrical contacts to the layer of polycrystalline IV-VI lead salt semiconductor material and the substrate to create a photovoltaic device which generates a voltage or electrical current based on changes in light interacting with the layer of polycrystalline IV-VI lead salt semiconductor material and the junction layer.

2. (canceled)

3. (canceled)

4. The method of claim 1, wherein the IV-VI lead salt semiconductor material is chosen from a group comprising PbSe, PbS, PbSnSe, PbTe, PbSnTe, PbSrSe, PbSrTe, PbEuSe, PbEuTe, PbCdSe, PbCdTe, and any lead salt containing a combination of two, three, four, or more Group IV and Group VI elements.

5. The method of claim 1, further comprising sensitizing the layer of polycrystalline IV-VI lead salt semiconductor material to enhance or create the ability of the layer of polycrystalline IV-VI lead salt semiconductor material's ability to receive and interact with the light.

6. The method of claim 5, wherein sensitizing the layer of polycrystalline IV-VI lead salt semiconductor material comprises annealing the layer of polycrystalline IV-VI lead salt semiconductor material in an iodine-containing atmosphere followed by an oxygen-containing atmosphere.

7. The method of claim 1, wherein applying the junction layer comprises depositing a Schottky contact layer on an upper surface of the layer of polycrystalline IV-VI lead salt semiconductor material.

8. The method of claim 7, wherein the Schottky contact layer is a Pb layer.

9. The method of claim 7, wherein applying the junction layer further comprises annealing the Schottky contact layer under a nitrogen-containing atmosphere.

10. The method of claim 1, wherein applying the junction layer comprises creating a p-n junction layer by doping.

11. The method of claim 1, further comprising applying an anti-reflective coating.

12. The method of claim 11, wherein the anti-reflective coating comprises CaF₂.

13. The method of claim 11, wherein the anti-reflective coating is applied to the layer of polycrystalline IV-VI lead salt semiconductor material.

14. The method of claim 11, wherein the anti-reflective coating is applied to a lower surface of the substrate, opposite an upper surface to which the layer of polycrystalline IV-VI lead salt semiconductor material is applied.

15. The method of claim 1, wherein the substrate is selected from the group consisting of planar substrates and curved substrates.

16. The method of claim 1, wherein the substrate is transparent to wavelengths within the infra-red spectrum.

17. A photovoltaic device, comprising:
a substrate having an upper surface and a lower surface;
a layer of polycrystalline IV-VI lead salt semiconductor material applied to the upper surface of the substrate, the layer of polycrystalline IV-VI lead salt semiconductor material comprising a plurality of microcrystals;
a junction layer applied to the polycrystalline IV-VI lead salt semiconductor material on a surface of the layer of polycrystalline IV-VI lead salt semiconductor material opposite a surface of the layer of polycrystalline IV-VI lead salt semiconductor material in contact with the upper surface of the substrate, the junction layer enabling changes in light interacting with the layer of polycrystalline IV-VI lead salt semiconductor material to create a changes at the junction layer; and
at least two or more spaced apart electrical contacts connected to the junction layer and to the substrate to enable generation of a voltage or electrical current based on changes in light interacting with the layer of polycrystalline IV-VI lead salt semiconductor material and the junction layer.

18. The photovoltaic device of claim 17, wherein the substrate is transparent to wavelength ranges of light able to be detected by the layer of polycrystalline IV-VI lead salt semiconductor material.

19. The photovoltaic device of claim 18, wherein the substrate is at least partially transparent to wavelengths of mid-infrared light.

20. The photovoltaic device of claim 19, wherein the substrate further comprises a mid-infrared transparent ohmic contact positioned on the upper surface of the substrate.

21. The photovoltaic device of claim 17, wherein the substrate is selected from the group consisting of rigid substrates and flexible substrates.

22. The photovoltaic device of claim 17, wherein the substrate is selected from the group consisting of planar substrates and non-planar substrates.

23. The photovoltaic device of claim 22, wherein the non-planar substrate is a curved substrate having a concave surface and a concave surface.

24. (canceled)

25. (canceled)

26. The photovoltaic device of claim 17, wherein the polycrystalline IV-VI lead salt semiconductor material is chosen from a group comprising PbSe, PbS, PbSnSe, PbTe, PbSnTe, PbSrSe, PbSrTe, PbEuSe, PbEuTe, PbCdSe, PbCdTe, and any lead salt containing a combination of two, three, four, or more Group IV and Group VI elements.

27. The photovoltaic device of claim 17, wherein the junction layer comprises a Schottky contact layer.

28. The photovoltaic device of claim 27, wherein the Schottky contact layer is a Pb layer.

29. The photovoltaic device of claim 17, wherein the junction layer comprises a p-n junction layer.

30. The photovoltaic device of claim 17, having an anti-reflective coating disposed on at least a portion thereof.

31. The photovoltaic device of claim 30, wherein the anti-reflective coating comprises CaF₂.

32. The photovoltaic device of claim 30, wherein the anti-reflective coating is applied to the layer of polycrystalline IV-VI lead salt semiconductor material.

33. The photovoltaic device of claim 30, wherein the anti-reflective coating is applied to the lower surface of the substrate, opposite the upper surface to which the layer of polycrystalline IV-VI lead salt semiconductor material is applied.

34. The photovoltaic device of claim 17, further comprising:
a microchannel plate configured to receive electrons emitted from the at least two or more spaced apart electrical contacts and generate information indicative of a pattern at which the electrons strike the microchannel plate;
a vacuum tube disposed between the at least two or more spaced apart electrical contacts and the microchannel plate, the vacuum tube configured to allow electrons emitted from the at least two or more spaced apart electrical contacts to strike the microchannel plate; and
one or more electronics configured to receive the information indicative of the pattern at which the electrons strike the microchannel plate and generate an image in the pattern at which the electrons strike the microchannel plate.

35. (canceled)

36. (canceled)

37. (canceled)

38. (canceled)

39. (canceled)

40. (canceled)

41. (canceled)

42. (canceled)

43. (canceled)

44. A compound eye photodetector, comprising:
a substrate having a first surface, and a second surface, opposite the first surface, the substrate being transparent to a range of wavelengths of light;
a plurality of photodetectors disposed on the first surface of the substrate, the photodetectors having at least one cell formed of a crystal surrounded by an insulating layer, the photodetectors able to detect the range of wavelengths of light passed by the substrate from the second surface to the first surface, wherein the plurality of photodetectors are formed from a layer of polycrystalline IV-VI lead salt semiconductor material;
a plurality of spaced apart electrical contacts connected to the photodetectors;
a plurality of lenses on the second surface of the substrate with each lens paired with at least one of the photodetectors; and
one or more electronics configured to receive information from the electrical contacts and generate an image based upon the information.

45. (canceled)

46. (canceled)

47. (canceled)

48. (canceled)

49. (canceled)

50. (canceled)
